(19) United States
(12) Patent Application Publication
(10) Pub. No.: US 2024/0282617 A1
(43) Pub. Date: Aug. 22, 2024

(54) SUBSTRATE PROCESSING APPARATUS AND SUBSTRATE PLACING METHOD

(71) Applicant: Tokyo Electron Limited, Tokyo (JP)

(72) Inventors: Kimio Motoda, Koshi City (JP); Kenji Sugakawa, Koshi City (JP); Norifumi Kohama, Koshi City (JP); Hideyuki Fukushima, Koshi City (JP); Shintaro Sugihara, Koshi City (JP); Norio Wada, Koshi City (JP)

(21) Appl. No.: 18/442,522

(22) Filed: Feb. 15, 2024

(30) Foreign Application Priority Data
Feb. 16, 2023 (JP) 2023-022849

(51) Int. Cl. H01L 21/683; H01L 21/67; H01L 21/68; H01L 21/687

(52) U.S. Cl. CPC H01L 21/6838; H01L 21/67288; H01L 21/681; H01L 21/68785

(57) ABSTRACT

A substrate processing apparatus is equipped with a holder having, on an attraction surface configured to attract a substrate, a circular central region and an annular outer region disposed outside the central region. The holder includes a first attracting pressure generator configured to generate an attracting pressure in the central region to attract the substrate to the holder; a second attracting pressure generator configured to generate an attracting pressure in the outer region to attract the substrate to the holder; and an external force applier configured to apply an external force to the substrate in the outer region in a direction in which the substrate becomes farther from the holder.

### CROSS-REFERENCE TO RELATED APPLICATION

This application claims the benefit of Japanese Patent Application No. 2023-022849 filed on Feb. 16, 2023, the entire disclosure of which is incorporated herein by reference.

### TECHNICAL FIELD

The various aspects and embodiments described herein pertain generally to a substrate processing apparatus and a substrate placing method.

### BACKGROUND

Patent Document 1 discloses a bonding apparatus equipped with an upper chuck for attracting a substrate at an upper side from above and a lower chuck for attracting a substrate at a lower side from below, and configured to bond the two substrates to face each other. To bond the substrates, the bonding apparatus presses a central portion of the substrate of the upper chuck into contact with a central portion of the substrate of the lower chuck, bonds the central portions of the two substrates to each other by an intermolecular force, and expands this bonding region from the central portions to outer peripheries of the substrates.

In a substrate processing apparatus equipped with such a chuck for attracting and holding a substrate as described above, when the substrate is simply attracted, there is a likelihood that a substrate processing is performed in a state that a residual stress on the substrate is large due to bending of the substrate or the like.

Patent Document 1: Japanese Patent Laid-open Publication No. 2015-095579

### SUMMARY

In one exemplary embodiment, there is provided a substrate processing apparatus equipped with a holder having, on an attraction surface configured to attract a substrate, a circular central region and an annular outer region disposed outside the central region. The holder includes a first attracting pressure generator configured to generate an attracting pressure in the central region to attract the substrate to the holder; a second attracting pressure generator configured to generate an attracting pressure in the outer region to attract the substrate to the holder; and an external force applier configured to apply an external force to the substrate in the outer region in a direction in which the substrate becomes farther from the holder.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view illustrating a bonding apparatus according to an exemplary embodiment of the present disclosure;

FIG. 2 is a side view of the bonding apparatus of FIG. 1;

FIG. 3 is a side view illustrating an example of a first substrate and a second substrate;

FIG. 4 is a flowchart illustrating a bonding method of the bonding apparatus;

FIG. 5 is a plan view illustrating an example of a bonding module according to a first exemplary embodiment;

FIG. 6 is a side view of the bonding module of FIG. 5;

FIG. 7 is a cross sectional view illustrating an example of an upper chuck and a lower chuck;

FIG. 8 is a flowchart illustrating details of a process S109 of FIG. 4;

FIG. 9A is a side view illustrating an example of an operation in a process S112 of FIG. 8;

FIG. 9B is a side view illustrating an operation following that of FIG. 9A;

FIG. 9C is a side view illustrating an operation following that of FIG. 9B;

FIG. 10A is a cross sectional view illustrating an example of an operation in a process S113 of FIG. 8;

FIG. 10B is a cross sectional view illustrating an example of an operation in a process S114 of FIG. 8;

FIG. 10C is a cross sectional view illustrating an operation following that of FIG. 10B;

FIG. 11 is a plan view illustrating an example of an attraction surface of the lower chuck;

FIG. 12A is a perspective view illustrating an example of bending of the lower wafer;

FIG. 12B is an explanatory diagram showing a relationship between the lower wafer that is bent concavely and an attraction state by the attraction surface;

FIG. 12C is an explanatory diagram showing a relationship between the lower wafer that is bent convexly and an attraction state by the attraction surface;

FIG. 13 is a side cross sectional view illustrating a state in which an external force is applied to the lower wafer by the lower chuck;

FIG. 14A is a flowchart illustrating an example of a substrate placing method;

FIG. 14B is a timing chart illustrating the example of the substrate placing method;

FIG. 15A is a diagram illustrating a first operation in the substrate placing method;

FIG. 15B is a diagram illustrating a second operation in the substrate placing method;

FIG. 15C is a diagram illustrating a third operation in the substrate placing method;

FIG. 16 is a side cross sectional view illustrating a lower chuck according to a first modification example; and

FIG. 17 is a side cross sectional view illustrating a lower chuck according to a second modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described with reference to the accompanying drawings. In the various drawings, like parts will be assigned like reference numerals, and redundant description will be omitted.

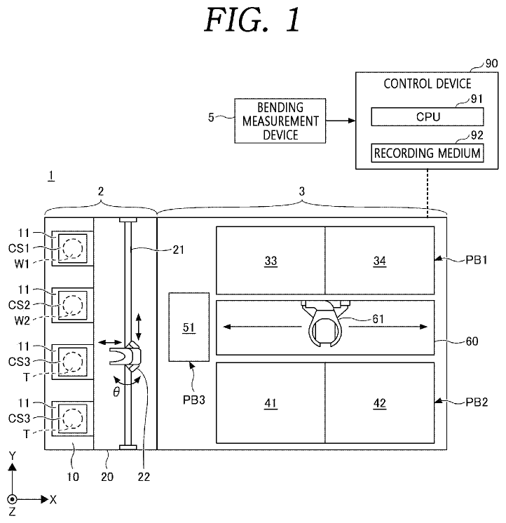

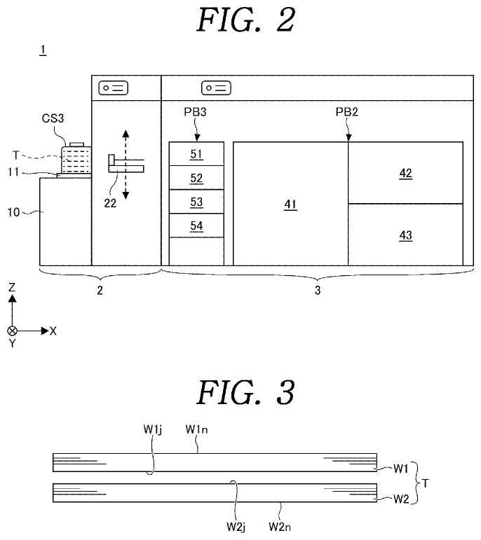

As a substrate processing apparatus according to the present disclosure, a bonding apparatus 1 shown in FIG. 1 and FIG. 2 will be described representatively. Here, however, it should be noted that the substrate processing apparatus of the present disclosure is not limited to the bonding apparatus 1 and may be any of various other apparatuses including a holder configured to hold a substrate and process the substrate held by the holder. Examples of other substrate processing apparatuses include an exposure apparatus, a temperature control apparatus, and so forth. The exposure apparatus is an apparatus configured to hold a substrate with a holder and transfer a mask pattern onto the substrate. The temperature control apparatus is an apparatus configured to hold a substrate with a holder and control a temperature of the substrate.

The bonding apparatus 1 is configured to produce a bonded substrate T by bonding a first substrate W1, which is one of substrates, and a second substrate W2, which is the other of the substrates, as shown in FIG. 3. At least one of the first substrate W1 and the second substrate W2 is a substrate on which a plurality of electronic circuits are formed on a semiconductor substrate such as, but not limited to, a silicon wafer or a compound semiconductor wafer. One of the first substrate W1 and the second substrate W2 may be a bare wafer on which no electronic circuit is formed. Although not particularly limited, the compound semiconductor wafer may be, for example, a GaAs wafer, a SiC wafer, a GaN wafer, or an InP wafer.

The first substrate W1 and the second substrate W2 are formed on circular plates having substantially the same shape (same diameter). The bonding apparatus 1 places the second substrate W2 on the negative Z-axis side of (vertically under) the first substrate W1, and bonds the first substrate W1 and the second substrate W2. Hereinafter, the first substrate W1 may sometimes be referred to as “upper wafer W1”; the second substrate W2, “lower wafer W2”; and the bonded substrate T, “bonded wafer T”. In addition, hereinafter, among plate surfaces of the upper wafer W1, the plate surface to be bonded to the lower wafer W2 will be referred to as “bonding surface W1j”, and the plate surface opposite to the bonding surface W1j will be referred to as “non-bonding surface W1n”. Likewise, among plate surfaces of the lower wafer W2, the plate surface to be bonded to the upper wafer W1 will be referred to as “bonding surface W2j”, and the plate surface opposite to the bonding surface W2j will be referred to as “non-bonding surface W2n”.

As depicted in FIG. 1, the bonding apparatus 1 is equipped with a carry-in/out station 2 and a processing station 3 which are arranged in this order along the positive X-axis direction. The carry-in/out station 2 and the processing station 3 are connected as one body.

The carry-in/out station 2 includes a placing table 10 and a transfer section 20. The placing table 10 is equipped with a multiple number of placing plates 11. Provided on the placing plates 11 are cassettes CS1, CS2 and CS3 each of which accommodates therein a plurality of (e.g., 25 sheets of) substrates horizontally. The cassette CS1 accommodates therein upper wafers W1; the cassette CS2, lower wafers W2; and the cassettes CS3, bonded wafers T. Further, the upper wafers W1 and the lower wafers W2 are accommodated in the cassette CS1 and the cassette CS2, respectively, with the bonding surfaces W1j and W2j facing upwards while being aligned in the same direction.

The transfer section 20 is provided adjacent to the positive X-axis side of the placing table 10, and is equipped with a transfer path 21 extending in the Y-axis direction and a transfer device 22 configured to be movable along the transfer path 21. The transfer device 22 is configured to be movable in the X-axis direction as well as in the Y-axis direction and pivotable around the Z-axis, and serves to transfer the upper wafers W1, the lower wafers W2, and the bonded wafers T between the cassettes CS1 to CS3 placed on the placing table 10 and a third processing block PB3 of the processing station 3 to be described later.

The processing station 3 has, for example, three processing blocks PB1, PB2, and PB3. The first processing block PB1 is provided on the rear side (positive Y-axis side of FIG. 1) of the processing station 3. The second processing block PB2 is provided on the front side (negative Y-axis side of FIG. 1) of the processing station 3. The third processing block PB3 is provided on the carry-in/out station 2 side (negative X-axis side of FIG. 1) of the processing station 3.

Further, the processing station 3 is equipped with a transfer section 60 having a transfer device 61 in a region surrounded by the first processing block PB1 to the third processing block PB3. For example, the transfer device 61 has a transfer arm configured to be movable in a vertical direction and a horizontal direction and pivotable around a vertical axis. The transfer device 61 is moved within the transfer section 60 to transfer the upper wafers W1, the lower wafers W2, and the bonded wafers T to devices within the first processing block PB1, the second processing block PB2, and the third processing block PB3 which are adjacent to the transfer section 60.

The first processing block PB1 includes, for example, a surface modifying apparatus 33 and a surface hydrophilizing apparatus 34. The surface modifying apparatus 33 is configured to modify the bonding surface W1j of the upper wafer W1 and the bonding surface W2j of the lower wafer W2. The surface hydrophilizing apparatus 34 is configured to hydrophilize the modified bonding surfaces W1j and W2j of the upper and lower wafers W1 and W2, respectively.

By way of example, the surfacy modifying apparatus 33 cuts a SiO₂ bond on the bonding surfaces W1j and W2j to form a dangling bond of Si, thus allowing the bonding surfaces W1j and W2j to be hydrophilized afterwards. In the surface modifying apparatus 33, an oxygen gas as a processing gas is excited into plasma to be ionized under a decompressed atmosphere, for example. As oxygen ions are radiated to the bonding surface W1j of the upper wafer W1 and the bonding surface W2j of the lower wafer W2, the bonding surfaces W1j and W2j are plasma-processed to be modified. The processing gas is not limited to the oxygen gas, but it may be a nitrogen gas or the like.

The surface hydrophilizing apparatus 34 is configured to hydrophilize the bonding surface W1j of the upper wafer W1 and the bonding surface W2j of the lower wafer W2 with a hydrophilizing liquid such as pure water. The surface hydrophilizing apparatus 34 also has a function of cleaning the bonding surfaces W1j and W2j. In this surface hydrophilizing apparatus 34, while rotating the upper wafer W1 or the lower wafer W2 held by, for example, a spin chuck, the pure water is supplied onto the upper wafer W1 or the lower wafer W2. Accordingly, the pure water is diffused on the bonding surfaces W1j and W2j, and an OH group is attached to the dangling bond of Si, so that the bonding surfaces W1j and W2j are hydrophilized.

As shown in FIG. 2, the second processing block PB2 includes, for example, a bonding module 41, a first temperature control device 42, and a second temperature control device 43. The bonding module 41 is configured to bond the hydrophilized upper wafer W1 and lower wafer W2 to produce the bonded wafer T. The first temperature control device 42 is configured to adjust a temperature distribution of the upper wafer W1 before producing the bonded wafer T. The second temperature control device 43 is configured to adjust a temperature distribution of the lower wafer W2 before producing the bonded wafer T. In addition, in the present exemplary embodiment, although the first temperature control device 42 and the second temperature control device 43 are provided separately from the bonding module 41, they may be provided as a part of the bonding module 41.

The third processing block PB3 is equipped with a first position adjusting device 51, a second position adjusting device 52, and transition devices 53 and 54 in this order from top to bottom, for example. Further, the places where the individual devices are disposed in the third processing block PB3 are not limited to the example shown in FIG. 2. The first position adjusting device 51 is configured to adjust a direction of the upper wafer W1 in a horizontal direction, and invert the upper wafer W1 upside down so that the bonding surface W1j of the upper wafer W1 faces downwards. The second position adjusting device 52 is configured to adjust a direction of the lower wafer W2 in a horizontal direction. The transition device 53 is configured to temporarily place therein the upper wafer W1. Further, the transition device 54 is configured to temporarily place therein the lower wafer W2 and the bonded wafer T.

Referring back to FIG. 1, the bonding apparatus 1 is equipped with a control device (controller) 90 configured to control the individual components. The control device 90 is a control computer having one or more processors 91, a memory 92, a non-illustrated input/output interface, and an electronic circuit. The one or more processors 91 are implemented by one of a CPU, GPU, an ASIC, an FPGA, and a circuit composed of a plurality of discrete semiconductors, or a combination thereof, and execute a program stored in the memory 92. The memory 92 includes a non-volatile memory and a volatile memory.

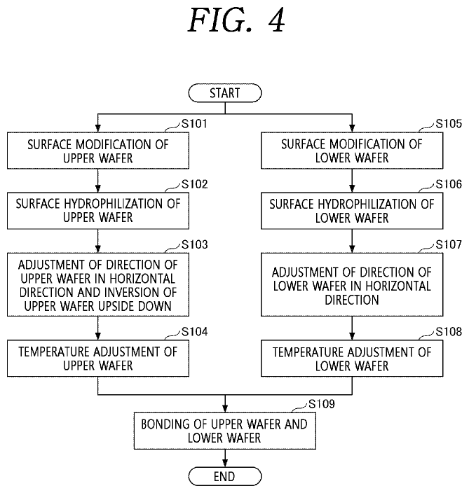

Now, referring to FIG. 4, a bonding method of the present exemplary embodiment will be explained. Processes S101 to S109 shown in FIG. 4 are performed under the control of the control device 90.

In the bonding method, an operator or a transfer robot (not shown) places the cassette CS1 accommodating therein the plurality of upper wafers W1, the cassette CS2 accommodating therein the plurality of lower wafers W2, and the empty cassette CS3 on the placing table 10 of the carry-in/out station 2.

The bonding apparatus 1 takes out the upper wafer W1 in the cassette CS1 by the transfer device 22, and transfers it to the transition device 53 of the third processing block PB3 of the processing station 3. Thereafter, the bonding apparatus 1 takes out the upper wafer W1 from the transition device 53 by the transfer device 61, and transfers it to the surface modifying apparatus 33 of the first processing block PB1.

Next, the bonding apparatus 1 modifies the bonding surface W1j of the upper wafer W1 by the surface modifying apparatus 33 (process S101). The surface modifying apparatus 33 modifies the bonding surface W1j in the state that the bonding surface W1j faces upwards. Then, the transfer device 61 takes out the upper wafer W1 from the surface modifying apparatus 33, and transfers it to the surface hydrophilizing apparatus 34.

Then, the bonding apparatus 1 hydrophilizes the bonding surface W1j of the upper wafer W1 by the surface hydrophilizing apparatus 34 (process S102). The surface hydrophilizing apparatus 34 hydrophilizes the bonding surface W1j in the state that the bonding surface W1j faces upwards. Thereafter, the transfer device 61 takes out the upper wafer W1 from the surface hydrophilizing apparatus 34, and transfers it to the first position adjusting device 51 of the third processing block PB3.

The bonding apparatus 1 adjusts the direction of the upper wafer W1 in the horizontal direction and inverts the upper wafer W1 upside down by the first position adjusting device 51 (process S103). As a result, a notch of the upper wafer W1 is directed in a predetermined direction, and the bonding surface W1j of the upper wafer W1 is turned to face downwards. Thereafter, the transfer device 61 takes out the upper wafer W1 from the first position adjusting device 51, and transfers it to the first temperature control device 42 of the second processing block PB2.

The bonding apparatus 1 adjusts the temperature of the upper wafer W1 by the first temperature control device 42 (process S104). The temperature adjustment of the upper wafer W1 is performed with the bonding surface W1j of the upper wafer W1 facing downwards. Thereafter, the transfer device 61 takes out the upper wafer W1 from the first temperature control device 42, and transfers it to the bonding module 41.

The bonding apparatus 1 performs a processing on the lower wafer W2 in parallel with the above-described processing on the upper wafer W1. First, the bonding apparatus 1 takes out the lower wafer W2 in the cassette CS2 by the transfer device 22, and transfers it to the transition device 54 of the third processing block PB3 of the processing station 3. Then, the transfer device 61 takes out the lower wafer W2 from the transition device 54, and transfers it to the surface modifying apparatus 33 of the first processing block PB1.

The bonding apparatus 1 modifies the bonding surface W2j of the lower wafer W2 by the surface modifying apparatus 33 (process S105). The surface modifying apparatus 33 modifies the bonding surface W2j in the state that the bonding surface W2j faces upwards. Thereafter, the transfer device 61 takes out the lower wafer W2 from the surface modifying apparatus 33, and transfers it to the surface hydrophilizing apparatus 34.

The bonding apparatus 1 hydrophilizes the bonding surface W2j of the lower wafer W2 by the surface hydrophilizing apparatus 34 (process S106). The surface hydrophilizing apparatus 34 hydrophilizes the bonding surface W2j in the state that the bonding surface W2j faces upwards. Then, the transfer device 61 takes out the lower wafer W2 from the surface hydrophilizing apparatus 34, and transfers it to the second position adjusting device 52 of the third processing block PB3.

The bonding apparatus 1 adjusts the direction of the lower wafer W2 in the horizontal direction by the second position adjusting device 52 (process S107). As a result, a notch of the lower wafer W2 is directed toward a predetermined direction. Thereafter, the transfer device 61 takes out the lower wafer W2 from the second position adjusting device 52, and transfers it to the second temperature control device 43 of the second processing block PB2.

The bonding apparatus 1 adjusts the temperature of the lower wafer W2 by the second temperature control device 43 (process S108). The temperature adjustment of the lower wafer W2 is performed with the bonding surface W2j of the lower wafer W2 facing upwards. Thereafter, the transfer device 61 takes out the lower wafer W2 from the second temperature control device 43, and transfers it to the bonding module 41.

Then, the bonding apparatus 1 bonds the upper wafer W1 and the lower wafer W2 in the bonding module 41 to produce the bonded wafer T (process S109). After the production of the bonded wafer T, the transfer device 61 takes out the bonded wafer T from the bonding module 41, and transfers it to the transition device 54 of the third processing block PB3.

Finally, the bonding apparatus 1 takes out the bonded wafer T from the transition device 54 by the transfer device 22, and transfers it to the cassette CS3 on the placing table 10. Thus, the series of processes are ended.

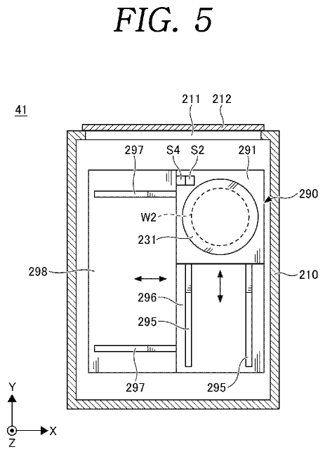

Now, with reference to FIG. 5 to FIG. 7, an example of the bonding module 41 according to the present exemplary embodiment will be described. As depicted in FIG. 5, the bonding module 41 is equipped with a processing vessel 210 having a sealable inside. A carry-in/out opening 211 is formed on a side surface of the processing vessel 210 on the transfer section 60 side, and an opening/closing shutter 212 is provided at the carry-in/out opening 211. The upper wafer W1, the lower wafer W2, and the bonded wafer T are carried in and out through the carry-in/out opening 211.

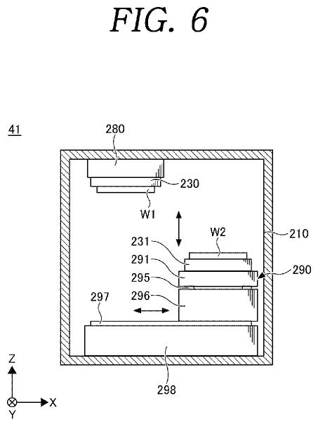

As shown in FIG. 6, an upper chuck 230 and a lower chuck 231 are provided inside the processing vessel 210. The upper chuck 230 is an upper holder configured to hold the upper wafer W1 from above while allowing the bonding surface W1j of the upper wafer W1 to face downwards. Further, the lower chuck 231 is disposed below the upper chuck 230, and serves as a holder configured to hold the lower wafer W2 from below while allowing the bonding surface W2j of the lower wafer W2 to face upwards.

The upper chuck 230 is supported by a supporting member 280 provided on a ceiling surface of the processing vessel 210. Meanwhile, the lower chuck 231 is supported by a first lower chuck mover 291 provided below the lower chuck 231.

The first lower chuck mover 291 moves the lower chuck 231 in a horizontal direction (Y-axis direction) as will be described later. Further, the first lower chuck mover 291 is configured to be capable of moving the lower chuck 231 in a vertical direction and rotating it around a vertical axis.

The first lower chuck mover 291 is mounted to a pair of rails 295 provided on a bottom surface side of the first lower chuck mover 291 and extending in the horizontal direction (Y-axis direction). The first lower chuck mover 291 is configured to be movable along the rails 295. The rails 295 are provided on the second lower chuck mover 296.

The second lower chuck mover 296 is mounted to a pair of rails 297 provided on a bottom surface side of the second lower chuck mover 296 and extending in a horizontal direction (X-axis direction). The second lower chuck mover 296 is configured to be movable along the rails 297. In addition, the pair of rails 297 are disposed on a placing table 298 which is provided on a bottom surface of the processing vessel 210.

The first lower chuck mover 291 and the second lower chuck mover 296 constitute a moving mechanism 290. The moving mechanism 290 moves the lower chuck 231 relative to the upper chuck 230. Further, the moving mechanism 290 moves the lower chuck 231 between a substrate delivery position and a bonding position.

The substrate delivery position is a position where the upper chuck 230 receives the upper wafer W1 from the transfer device 61, the lower chuck 231 receives the lower wafer W2 from the transfer device 61, and the lower chuck 231 delivers the bonded wafer T to the transfer device 61. The substrate delivery position is a position where a carry-out of the bonded wafer T produced by the n^{th} (n is a natural number equal to or larger than 1) bonding and a carry-in of the upper wafer W1 and the lower wafer W2 to be bonded by the (n+1)^{th} bonding are performed in succession. The substrate delivery position is, for example, a position shown in FIG. 5 and FIG. 6.

When handing the upper wafer W1 over to the upper chuck 230, the transfer device 61 advances to a space directly below the upper chuck 230. Further, when receiving the bonded wafer T from the lower chuck 231 and handing the lower wafer W2 over to the lower chuck 231, the transfer device 61 advances to a space directly above the lower chuck 231. The upper chuck 230 and the lower chuck 231 are placed sideways apart, and a distance between the upper chuck 230 and the lower chuck 231 in a vertical direction is large so that the transfer device 61 advances therebetween easily.

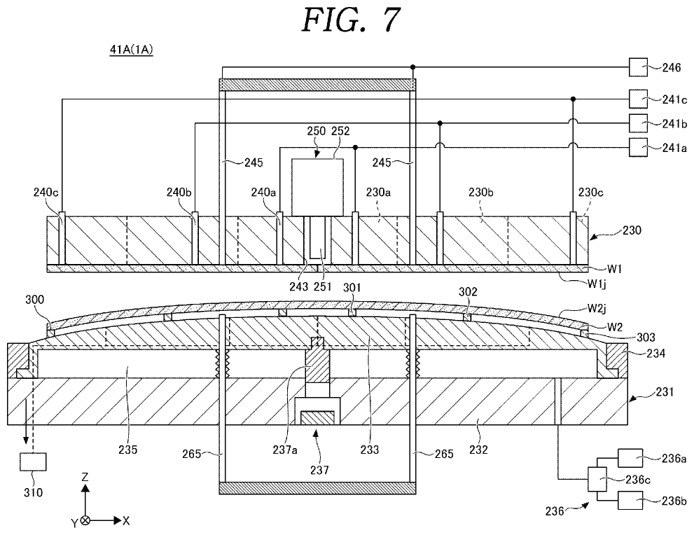

Meanwhile, the bonding position is a position (facing position) where the upper wafer W1 and the lower wafer W2 are made to face each other at a preset distance therebetween. The bonding position is, for example, a position shown in FIG. 7. At the bonding position, the distance between the upper wafer W1 and the lower wafer W2 in the vertical direction is narrower than that at the substrate delivery position. Further, at the bonding position, the upper wafer W1 and the lower wafer W2 overlap each other when viewed from the vertical direction, unlike at the substrate delivery position.

The moving mechanism 290 moves the relative positions of the upper chuck 230 and the lower chuck 231 in horizontal directions (both the X-axis direction and the Y-axis direction) and a vertical direction. Although the moving mechanism 290 moves the lower chuck 231 in the present exemplary embodiment, it may move any one of the lower chuck 231 and the upper chuck 230, or both of them. Further, the moving mechanism 290 may rotate the upper chuck 230 or the lower chuck 231 around a vertical axis.

As illustrated in FIG. 7, the upper chuck 230 is divided into a plurality of (for example, three) regions 230a, 230b, and 230c along a radial direction of the upper chuck 230. These regions 230a, 230b, and 230c are provided in this order from a center of the upper chuck 230 toward an outer periphery thereof. The region 230a is formed in a circular shape when viewed from the top, and the regions 230b and 230c are formed in an annular shape when viewed from the top.

Suction lines 240a, 240b, and 240c are independently provided in the regions 230a, 230b, and 230c, respectively. Different vacuum pumps 241a, 241b, and 241c are connected to the suction lines 240a, 240b, and 240c, respectively. The upper chuck 230 is capable of vacuum-attracting the upper wafer W1 in each of the regions 230a, 230b, and 230c individually.

The upper chuck 230 is provided with a multiple number of holding pins 245 configured to be movable up and down in a vertical direction. The plurality of holding pins 245 are connected to a vacuum pump 246, and the upper wafer W1 is vacuum-attracted to the holding pins 245 by the operation of the vacuum pump 246. The upper wafer W1 is vacuum-attracted to lower ends of the plurality of holding pins 245. Instead of the plurality of holding pins 245, a ring-shaped attraction pad may be used.

The plurality of holding pins 245 are protruded from an attraction surface of the upper chuck 230 as they are lowered by a non-illustrated driving unit. In this state, the plurality of holding pins 245 receives the upper wafer W1 from the transfer device 61 by vacuum-attracting it. Thereafter, the plurality of holding pins 245 are raised, allowing the upper wafer W1 to come into contact with the attraction surface of the upper chuck 230. Then, the upper chuck 230 vacuum-attracts the upper wafer W1 horizontally in the respective regions 230a, 230b, and 230c by the operations of the vacuum pumps 241a, 241b, and 241c, respectively.

In addition, the upper chuck 230 has, at the center thereof, a through hole 243 formed through the upper chuck 230 in a vertical direction. A pushing member 250 is disposed near the through hole 243. The pushing member 250 presses the center of the upper wafer W1 distanced apart from the lower wafer W2, thus bringing the upper wafer W1 into contact with the lower wafer W2.

The pushing member 250 has a pushing pin 251 and an outer cylinder 252 serving as an elevation guide for the pushing pin 251. The pushing pin 251 is inserted through the through hole 243 by, for example, a driver (not shown) having a motor therein, and is protruded from the attraction surface of the upper chuck 230, pressing the center of the upper wafer W1.

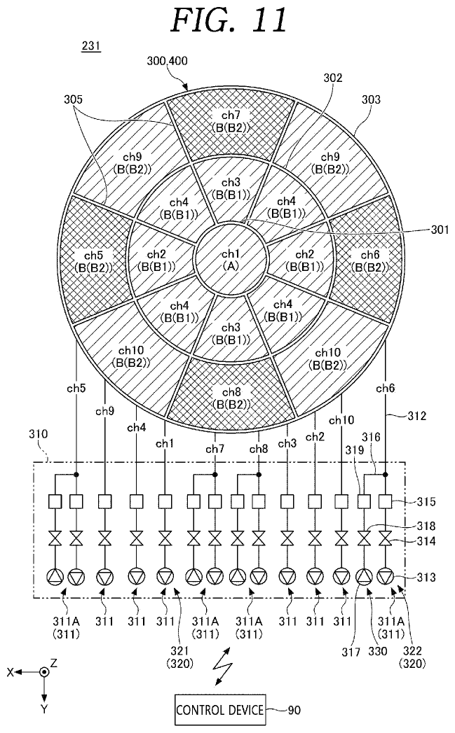

Moreover, the lower chuck 231 also has a plurality of partitioned regions in an attraction surface 300 for attracting the lower wafer W2. A top surface of the lower chuck 231 is provided with ribs 301, 302 and 303 each having an annular shape and a rib 305 having a radial shape (see FIG. 11). The attraction surface 300 is formed by upper ends of the ribs 301, 302, and 305. The configuration of the attraction surface 300 of the lower chuck 231 will be described in detail later.

The lower chuck 231 is provided with a plurality of (for example, three) lift pins 265 configured to be movable up and down in a vertical direction. The plurality of lift pins 265 are protruded from the attraction surface 300 of the lower chuck 231 as they are raised. Further, the lift pins 265 receive the lower wafer W2 as they are raised with respect to the lower wafer W2 carried in by the transfer device 61. Furthermore, the lift pins 265 are lowered after the transfer device 61 is retreated, thus allowing the lower wafer W2 to be placed on the attraction surface 300. Also, the lift pins 265 may vacuum-attract the lower wafer W2 when they receive the lower wafer W2.

In addition, the lower chuck 231 according to the present exemplary embodiment is configured to transform the attraction surface 300. The lower chuck 231 includes, for example, a base 232 and an attraction member 233. The attraction member 233 is provided above the base 232 to attract and hold the lower wafer W2 from below. The attraction member 233 is formed in a circular shape with a diameter larger than that of the lower wafer W2 when viewed from the top, and is fixed to the base 232 by a fastening ring 234 provided at a periphery thereof.

In addition, the lower chuck 231 has a pressure-variable space 235 between a top surface of the base 232 and a bottom surface of the attraction member 233, and is equipped with a transformation controller 236 configured to elastically transform the attraction member 233 by varying the pressure of the pressure-variable space 235. The attraction member 233 is made of, for example, ceramic such as alumina or silicon carbide.

The transformation controller 236 includes a vacuum pump 236a, a booster pump 236b, and a switching valve 236c. The vacuum pump 236a decompresses the pressure-variable space 235 by discharging a gas in the pressure-variable space 235. As the pressure-variable space 235 is decompressed, a top surface of the attraction member 233 becomes a horizontal surface or a curved surface with a recessed center side. Meanwhile, the booster pump 236b pressurizes the pressure-variable space 235 by supplying a gas to the pressure-variable space 235. As the pressure-variable space 235 is pressurized, the attraction surface 300 becomes a curved surface with a protruding center side. A transformation amount of the attraction surface 300 may be adjusted by controlling the pressure of the pressure variable space 235. The switching valve 236c switches the pressure-variable space 235 between a state in which it is connected to the vacuum pump 236a and a state in which it is connected to the booster pump 236b.

The base 232 has a measurer 237 configured to measure a protrusion amount of a central region A of the attraction surface 300. A measurement target 237a of the measurer 237 is moved up and down along with a central portion of the attraction member 233. The measurer 237 is, for example, a capacitance sensor, and measures the protrusion amount by detecting electrostatic capacitance which varies depending on a distance with respect to the measurement target 237a. The bonding module 41 configured as described above is capable of attracting and holding the lower wafer W2 transferred by the transfer device 61 while transforming the attraction surface 300 of the lower chuck 231 into an appropriate shape before the lower wafer W2 is held on the attraction surface 300.

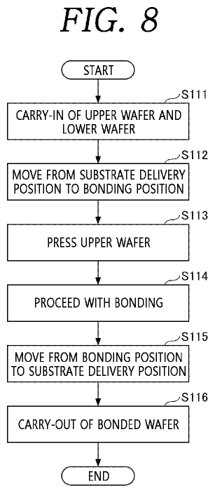

Now, with reference to FIG. 8 to FIG. 10C, the process of manufacturing the bonded wafer T in the process S109 of FIG. 4 will be described in detail. As depicted in FIG. 8, the control device 90 controls the transfer device 61 to carry the upper wafer W1 and the lower wafer W2 into the bonding module 41 (process S111). The relative positions of the upper chuck 230 and the lower chuck 231 after being carried in are at the substrate delivery position, as illustrated in FIG. 5 and FIG. 6.

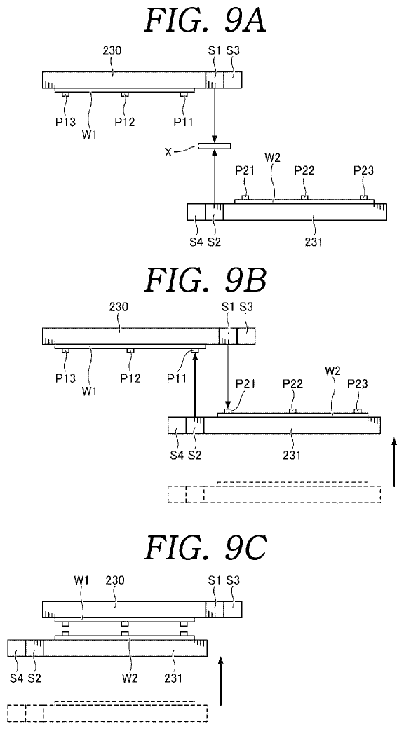

Subsequently, the control device 90 controls the moving mechanism 290 to move the relative positions of the upper chuck 230 and the lower chuck 231 from the substrate delivery position to the bonding position shown in FIG. 7 (process S112). In this process S112, the control device 90 carries out position-alignment between the upper wafer W1 and the lower wafer W2 by using a first camera S1 and a second camera S2 as shown in FIG. 9A to FIG. 9C.

The first camera S1 is fixed to the upper chuck 230 to image the lower wafer W2 held by the lower chuck 231. Multiple reference points P21 to P23 are previously formed on the bonding surface W2j of the lower wafer W2. As the reference points P21 to P23, patterns of electronic circuits, electrode pads, or the like may be used. The number of the reference points is not particularly limited.

Meanwhile, the second camera S2 is fixed to the lower chuck 231 to image the upper wafer W1 held by the upper chuck 230. Multiple reference points P11 to P13 are formed in advance on the bonding surface W1j of the upper wafer W1. As the reference points P11 to P13, patterns of electronic circuits or the like may be used. The number of these reference points is not particularly limited.

As depicted in FIG. 9A, the bonding module 41 adjusts the relative positions of the first camera S1 and the second camera S2 in a horizontal direction through the use of the moving mechanism 290. Specifically, the moving mechanism 290 moves the lower chuck 231 in the horizontal direction such that the second camera S2 is positioned substantially directly below the first camera S1. Then, the first camera S1 and the second camera S2 image a common target X and the moving mechanism 290 finely adjusts the position of the second camera S2 in the horizontal direction such that the positions of the first camera S1 and the second camera S2 in the horizontal direction are coincident.

Subsequently, as shown in FIG. 9B, the moving mechanism 290 moves the lower chuck 231 vertically upwards to adjust the positions of the upper chuck 230 and the lower chuck 231 in the horizontal direction. Specifically, while the moving mechanism 290 moves the lower chuck 231 in the horizontal direction, the first camera S1 sequentially images the reference points P21 to P23 of the lower wafer W2, and the second camera S2 sequentially images the reference points P11 to P13 of the upper wafer W1. FIG. 9B shows a state in which the first camera S1 is imaging the reference point P21 of the lower wafer W2 and the second camera S2 is imaging the reference point P11 of the upper wafer W1.

The first camera S1 and the second camera S2 transmit the obtained image data to the control device 90. The control device 90 controls the moving mechanism 290 based on the image data obtained by the first camera S1 and the image data obtained by the second camera S2, and adjusts the position of the lower chuck 231 in the horizontal direction such that the reference points P11 to P13 of the upper wafer W1 and the reference points P21 to P23 of the lower wafer W2 coincide with each other when viewed from the vertical direction.

Thereafter, as illustrated in FIG. 9C, the moving mechanism 290 moves the lower chuck 231 vertically upwards. As a result, a distance G (see FIG. 7) between the bonding surface W2j of the lower wafer W2 and the bonding surface W1j of the upper wafer W1 becomes a predetermined distance of, e.g., 80 μm to 200 μm. The adjustment of the distance G is performed by using a first displacement meter S3 and a second displacement meter S4.

The first displacement meter S3 is fixed to the upper chuck 230, and measures the thickness of the lower wafer W2 held by the lower chuck 231. The first displacement meter S3 measures the thickness of the lower wafer W2 by, for example, radiating light to the lower wafer W2 held by the lower chuck 231 and receiving reflected light reflected from both top and bottom surfaces of the lower wafer W2. This thickness measurement is performed when the moving mechanism 290 moves the lower chuck 231 in the horizontal direction, for example. The first displacement meter S3 carries out the measurement by, for example, a confocal method, a spectral interference method, or a triangulation method. A light source of the first displacement meter S3 may be an LED or a laser.

Meanwhile, the second displacement meter S4 is fixed to the lower chuck 231, and measures the thickness of the upper wafer W1 held by the upper chuck 230. The second displacement meter S4 measures the thickness of the upper wafer W1 by, for example, radiating light to the upper wafer W1 held by the upper chuck 230 and receiving reflected light reflected from both top and bottom surfaces of the upper wafer W1. This thickness measurement is performed when the moving mechanism 290 moves the lower chuck 231 in the horizontal direction, for example. The second displacement meter S4 carries out the measurement by, for example, a confocal method, a spectral interference method, or a triangulation method. A light source of the second displacement meter S4 may be an LED or a laser.

The first displacement meter S3 and the second displacement meter S4 transmit the measured data to the control device 90. The control device 90 controls the moving mechanism 290 based on the data obtained by the first displacement meter S3 and the data obtained by the second displacement meter S4, and adjusts the position of the lower chuck 231 in the vertical direction such that the distance G becomes a set value.

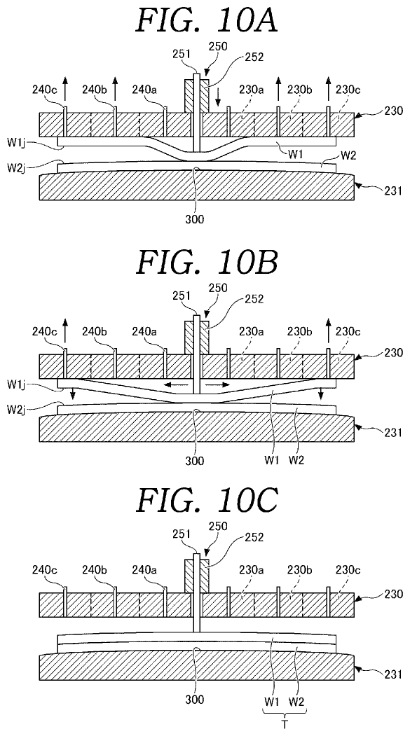

Next, after the gap G between the upper wafer W1 and the lower wafer W2 is adjusted, the operation of the vacuum pump 241a is stopped, thus canceling the vacuum attraction of the upper wafer W1 in the region 230a, as shown in FIG. 10A. Thereafter, the pushing pin 251 of the pushing member 250 is lowered to press the center of the upper wafer W1, allowing the upper wafer W1 to come into contact with the lower wafer W2 (process S113). As a result, the centers of the upper wafer W1 and the lower wafer W2 are bonded to each other.

Since the bonding surface W1j of the upper wafer W1 and the bonding surface W2j of the lower wafer W2 are modified, a van der Waals force (intermolecular force) is first generated between the bonding surfaces W1j and W2j, so that the bonding surfaces W1j and W2j are bonded to each other. Further, since the bonding surface W1j of the upper wafer W1 and the bonding surface W2j of the lower wafer W2 have been hydrophilized, hydrophilic groups (e.g., OH groups) are hydrogen-bonded, allowing the bonding surfaces W1j and W2j to be firmly bonded to each other.

Subsequently, the control device 90 stops the operation of the vacuum pump 241b, and cancels the vacuum attraction of the upper wafer W1 in the region 230b, as shown in FIG. 10B. Afterwards, the control device 90 stops the operation of the vacuum pump 241c, and cancels the vacuum attraction of the upper wafer W1 in the region 230c, as shown in FIG. 10C.

In this way, the vacuum attraction of the upper wafer W1 is released step by step from the center toward a periphery of the upper wafer W1, so that the upper wafer W1 drops and comes into contact with the lower wafer W2 step by step. Then, the bonding of the upper wafer W1 and the lower wafer W2 proceeds sequentially toward the peripheries of the upper and lower wafers W1 and W2 from the centers thereof (process S114). As a result, the entire bonding surface W1j of the upper wafer W1 and the entire bonding surface W2j of the lower wafer W2 come into contact with each other, so that the upper wafer W1 and the lower wafer W2 are bonded together, and the bonded wafer T is obtained. Then, the bonding apparatus 1 raises the pushing pin 251 to its original position.

Referring back to FIG. 8, after the bonded wafer T is formed, the control device 90 controls the moving mechanism 290 to move the relative positions of the upper chuck 230 and the lower chuck 231 from the bonding positions shown in FIG. 7 to the substrate delivery positions shown in FIG. 5 and FIG. 6 (process S115). By way of example, the moving mechanism 290 first lowers the lower chuck 231 to widen the distance between the lower chuck 231 and the upper chuck 230 in the vertical direction. Then, the moving mechanism 290 moves the lower chuck 231 sideways so that the lower chuck 231 and the upper chuck 230 are placed sideways apart.

Thereafter, the control device 90 controls the transfer device 61 to carry out the bonded wafer T from the bonding module 41 (process S116). Specifically, the lower chuck 231 first releases the holding of the bonded wafer T. Then, the plurality of lift pins 265 are raised to hand the bonded wafer T over to the transfer device 61. Thereafter, the plurality of holding pins 265 are lowered to their original positions.

Now, the configuration of the attraction surface 300 of the lower chuck 231 will be described with reference to FIG. 11. FIG. 11 is a plan view illustrating the attraction surface 300 of the lower chuck 231. The attraction surface 300 of the lower chuck 231 has a plurality of regions that are arranged in a radial direction thereof to generate an attracting pressure individually.

For example, the attraction surface 300 is partitioned into a central region A of a circular shape and an outer region B of an annular shape by annular ribs 301, 302, and 303. Further, the outer region B includes a first outer region B1 of an annular shape outside and adjacent to the central region A; and a second outer region B2 of an annular shape outside and adjacent to the first outer region B1. That is, the central region A, the first outer region B1, and the second outer region B2 are concentrically arranged in this order radially outwards from a center of the attraction surface 300. Alternatively, the first outer region B1 and the second outer region B2 may not be separated, and the attraction surface 300 may be partitioned into the central region A and the single outer region B that are arranged in this order radially outwards. To the contrary, the outer region B of the attraction surface 300 may include three or more annular regions.

The first outer region B1 is divided into eight arc-shaped zones (small regions: one part) by a plurality of ribs 305 that are arranged radially. Likewise, the second outer region B2 is also divided into eight arc-shaped zones by the ribs 305. Here, the number of the divisions of the first outer region B1 may be equal to or different from the number of the divisions of the second outer region B2, and their positions in a circumferential direction may be deviated from each other.

The central region A, the eight zones of the first outer region B1, and the eight zones of the second outer region B2 are configured to be capable of suctioning the lower wafer W2 individually. Here, however, in the lower chuck 231 according to the present exemplary embodiment, ten adjusting mechanisms 311 are connected to the total of seventeen zones, and the attraction surface 300 are suctioned for the zones of ten channels. That is, the attraction surface 300 has, among the total of seventeen zones, zones in which the suctioning is performed by the same adjusting mechanism 311.

To be more specific, the central region A is comprised of a single zone ch1. Meanwhile, in the first outer region B1, three zones ch2 to ch4 are set. The two zones adjacent to each other in the X-axis direction (a left-and-right direction in FIG. 11) with the central region A therebetween are the zones ch2. The two zones adjacent to each other in the Y-axis direction (an up-and-down direction in FIG. 11) with the central region A therebetween are the zones ch3. Further, in the outer region B, the four zones interposed between the zones ch2 and the zones ch3 are the zones ch4. In the second outer region B2, six zones ch5 to ch10 are set. The one zone adjacent to the first outer region B1 in the positive X-axis direction (left side in FIG. 11) is the zone ch5. The one zone adjacent to the first outer region B1 in the negative X-axis direction (right side in FIG. 11) is the zone ch6. The one zone adjacent to the first outer region B1 in the negative Y-axis direction (upper side in FIG. 11) is the zone ch7. The one zone adjacent to the first outer region B1 in the positive Y-axis direction (lower side in FIG. 11) is the zone ch8. Further, in the second outer region B2, the zone interposed between the zone ch5 and the zone ch7 and the zone interposed between the zone ch6 and the zone ch7 are the zones ch9. Likewise, in the second outer region B2, the zone interposed between the zone ch5 and the zone ch8 and the zone interposed between the zone ch6 and the zone ch8 are the zones ch10.

On the X-axis passing through the center of the attraction surface 300, the zones of ch5, ch2, ch1, ch2, and ch6 are arranged in this sequence from the positive X-axis side toward the negative X-axis side. On the Y-axis passing through the center of the attraction surface 300, the zones of ch7, ch3, ch1, ch3, and ch8 are arranged in this sequence from the negative Y-axis side toward the positive Y-axis side. Here, however, it should be noted that the attraction surface 300 can be designed as required for the number and the location of the channels of the respective zones without being limited to the shown example.

Connected to the lower chuck 231 is a gas controller 310 configured to perform suctioning or discharging of air to the respective zones of the attraction surface 300. Specifically, the gas controller 310 is equipped with ten adjusting mechanisms 311 respectively connected to the ten channels. Further, the gas controller 310 is connected to the control device 90 so as to be able to communicate with it, and operates the respective adjusting mechanisms 311 under the control of the control device 90.

Some of the adjusting mechanisms 311 may have only an attracting pressure generator 320 configured to generate an attracting pressure in the connected zone, and others may have an external force applier 330 configured to discharge the air from the connected zone in addition to the attracting pressure generator 320. Hereinafter, the adjusting mechanism 311 having both the attracting pressure generator 320 and the external force applier 330 will also be referred to as an adjusting mechanism 311A.

The attracting pressure generator 320 has a flow line 312 connected to the predetermined zone of the lower chuck 231 as well as a suction pump 313, an opening/closing valve 314, and a pressure controller 315 that are provided in this flow line 312. The attracting pressure generator 320 opens the opening/closing valve 314 by operating the suction pump 313 of the flow line 312, thus generating an attracting pressure (negative pressure) in the zone to which the flow line 312 is connected. The magnitude of the attracting pressure is controlled by the pressure controller 315. Further, each adjusting mechanism 311 release the attracting pressure of each zone by closing the opening/closing valve 314 of the preset flow line 312 and introducing air through the pressure controller 315.

The adjusting mechanism 311 having only the attracting pressure generator 320 is connected to the zone ch1, which is the central region A. Hereinafter, the attracting pressure generator 320 configured to generate the attracting pressure in the central region A is also referred to as a first attracting pressure generator 321. Meanwhile, in the zones ch2 to ch10, which are the outer region B, the adjusting mechanism 311 having only the attracting pressure generator 320 and the adjusting mechanism 311A including the attracting pressure generator 320 and the external force applier 330 are provided together. Hereinafter, the attracting pressure generator 320 configured to generate the attracting pressure in the outer region B is also referred to as a second attracting pressure generator 322.

To elaborate, in the outer region B, the zones to which the adjusting mechanism 311 (including only the second attracting pressure generator 322) is connected are the zones ch2 to ch4, ch9, and ch10. In the outer region B, the zones to which the adjusting mechanism 311A (including the second attracting pressure generator 322 and the external force applier 330) is connected are the zones ch5 to ch8. Further, in FIG. 11, the zones to which only the attracting pressure generator 320 is connected are indicated by single hatching, whereas the zones to which the attracting pressure generator 320 and the external force applier 330 are connected are indicated by cross hatching.

The external force applier 330 of each adjusting mechanism 311A enables blowing out air in an upward direction (positive Z-axis direction) of the attraction surface 300. This external force applier 330 has a force-feeding line 316 connected to the flow line 312, and the force-feeding line 316 is provided with a force-feeding pump 317, an opening/closing valve 318, and a flow rate regulator 319. Under the control of the control device 90, each external force applier 330 operates the force-feeding pump 317 of the designated force-feeding line 316 to open the opening/closing valve 318. As a result, the air is supplied from the force-feeding line 316 to the flow line 312, and this air is discharged upwards through a hole (not shown), which is also commonly used to apply the attracting pressure, in the zone to which the flow line 312 is connected. Further, the control device 90 is capable of controlling the size of the discharged air by the flow rate regulator 319. In addition, the external force applier 330 may be connected to the lower chuck 231 besides the flow line 312, and configured to discharge the air upwards through a hole (not shown) different from the hole used at the time of applying the attracting pressure.

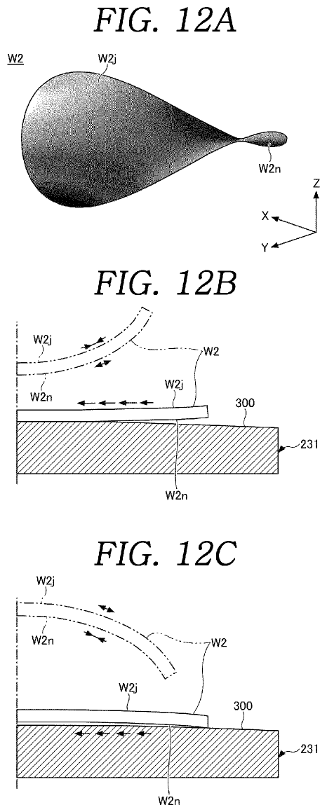

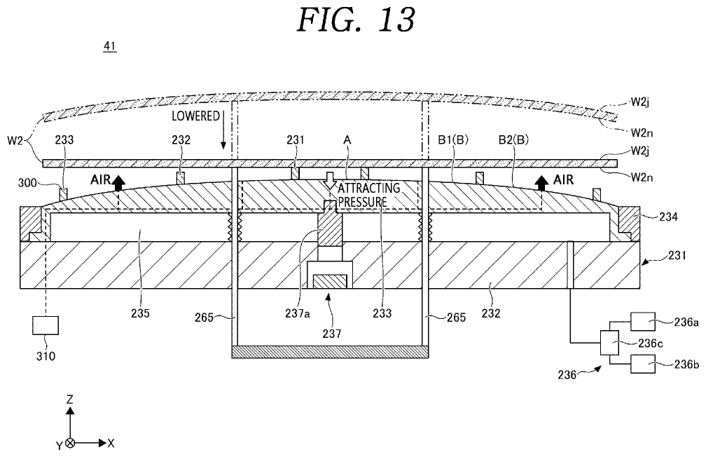

Now, referring to FIG. 12A to FIG. 12C, bending that occurs in the lower wafer W2 will be described. In FIG. 12A, black and white gradation indicates the height of the top surface (bonding surface W2j) of the lower wafer W2 with respect to the attraction surface 300 of the lower chuck 231. As the color is closer to black, the height of the top surface of the lower wafer W2 becomes lower and the gap between the top surface of the lower wafer W2 and the attraction surface 300 of the lower chuck 231 becomes smaller.

The bending of the lower wafer W2 is measured by, for example, a bending measurement device 5 (see FIG. 1) that is provided separately from the bonding apparatus 1, and the control device 90 acquires information on the bending state of the lower wafer W2 measured by the bending measurement device 5. Further, the bending measurement device 5 may be provided as a part of the bonding apparatus 1. The bonding apparatus 1 may be configured to measure the bending by using a plurality of displacement meters (not shown) provided in the bonding module 41 when the upper wafer W1 or the lower wafer W2 is carried in. The bending is measured when no external force (e.g., the attracting pressure) other than gravity and its reaction force is acting. For example, the bending is measured in the state that the wafer is placed on a flat surface of a stage or on a plurality of (e.g., three) pins.

Before the attracting pressure in the attraction surface 300 of the lower chuck 231 is generated by the gas controller 310 (see FIG. 11), the lower wafer W2 may be bent as shown in FIG. 12A. The bending of the lower wafer W2 occurs when, for example, a plurality of films are stacked on a semiconductor substrate such as a silicon wafer. Each film is formed by a CVD (Chemical Vapor Deposition) method, an ALD (Atomic Layer Deposition) method, a spin-on method, or the like. A stress is applied to the lower wafer W2 due to a difference in thermal expansion during the film formation, causing the lower wafer W2 to be bent.

The lower wafer W2 is often symmetrically bent with respect to two orthogonal straight lines in the radial direction, that is, axisymmetrically bent. This is because a Young's modulus, a Poisson's ratio, and a shear modulus of the semiconductor substrate such as the silicon wafer change at a cycle of 90°. The two orthogonal straight lines in the radial direction extend along a specific crystal orientation of the semiconductor substrate when viewed from a direction (Z-axis direction) perpendicular to the attraction surface 300.

The bonding apparatus 1 moves the lower wafer W2 from the transfer device 61 to the lower chuck 231 so that two orthogonal straight lines in the radial direction of the lower wafer W2 are aligned with the X-axis direction and the Y-axis direction of the lower chuck 231. For example, the direction (posture) of the lower wafer W2 is adjusted by the second position adjusting device 52 (see FIG. 2) described above.

The bending of the lower wafer W2 is either in a form in which outer edges of the lower wafer W2 at symmetrical positions with respect to the center of the lower wafer W2 are bent in a direction (vertically downward direction) in which they get closer to the attraction surface 300, or in a form in which the outer edges at the symmetrical positions are bent in a direction (vertically upward direction) in which they get away from the attraction surface 300. Hereinafter, the bending (protruding upwards) in which the outer edges of the lower wafer W2 are directed downwards, that is, the bending in which the central portion of the lower wafer W2 is further away from the attraction surface 300 than the outer edges thereof will be referred to as convex bending. Further, the bending (recessed upwards) in which the outer edges of the lower wafer W2 are directed upwards, that is, the bending in which the outer edges of the lower wafer W2 are further away from the attraction surface 300 than the central portion thereof will be referred to as concave bending.

For example, in the case where the lower wafer W2 is bent in the convex bending from two outer edges on the Y-axis toward the center thereof, it is formed as a saddle-shaped curved surface that is gently curved in the concave bending from two outer edges on the X-axis toward the center. Conversely, in the case where the lower wafer W2 is bent in the concave bending from the two outer edges on the Y-axis toward the center, it is formed as a saddle-shaped curved surface that is gently curved in the convex bending from the two outer edges on the X-axis toward the center. In other words, the bending of the lower wafer W2 occurs in opposite directions along two orthogonal straight lines in the radial direction.

As depicted in FIG. 12B, on an axis where the concave bending occurs in the lower wafer W2, a stress is applied such that the top surface (bonding surface W2j) is contracted in overall while the bottom surface (non-bonding surface W2n) is stretched in overall. As a result, when the lower wafer W2 is placed on the lower chuck 231 without applying any external force thereto, the stress causing the top surface of the lower wafer W2 to be contracted inwards remains on the axis of the concave bending of the lower wafer W2.

Meanwhile, as shown in FIG. 12C, on an axis where the convex bending occurs in the lower wafer W2, a stress is applied such that the top surface (bonding surface W2j) is stretched in overall while the bottom surface (non-bonding surface W2n) is contracted in overall. As a result, when the lower wafer W2 is placed on the lower chuck 231 without applying any external force thereto, the stress causing the bottom surface of the lower wafer W2 to be contracted inwards remains on the axis of the convex bending of the lower wafer W2.

That is, the bent lower wafer W2 contains the residual stress directed to the inside of its surface (top surface, bottom surface). A deviation between the upper wafer W1 and the lower wafer W2 after being bonded to each other is deemed to increase due to this residual stress. In view of this, the lower chuck 231 according to the present exemplary embodiment is configured to apply an external force to the lower wafer W2 from the appropriate channels (ch5 and ch6, or ch7 and ch8) in the outer region B, thus relieving the residual stress of the lower wafer W2.

Hereinafter, an operation when placing the bent lower wafer W2 on the lower chuck 231 will be explained. FIG. 13 is a side view illustrating the operation of placing the lower wafer W2 on the lower chuck 231.

As shown in FIG. 13, the bonding module 41 lowers the lower wafer W2 supported by the respective lift pins 265, allowing the lower wafer W2 to be placed on the attraction surface 300 of the lower chuck 231. At this time, the adjustment mechanism 311 (first attracting pressure generator 321) connected to the zone ch1 generates an attracting pressure of a predetermined pressure value in the central region A via the flow line 312, so that the central portion of the lower wafer W2 is attracted to and held in the central region A (see FIG. 11 as well).

Meanwhile, the pair of second outer regions B2 (ch5 and ch6) on the axis (X-axis in FIG. 13) where the convex bending has occurred is connected with the adjusting mechanism 311A having the external force applier 330. This external force applier 330 is capable of discharging air at an adjusted flow rate to both outer peripheral portions on the axis of the convex bending via the flow line 312. Meanwhile, the bonding module 41 does not operate the external force applier 330 of the adjusting mechanism 311A connected to the pair of second outer regions B2 (ch7 and ch8) where the concave bending has occurred.

That is, the lower wafer W2 receives a force (external force) from below in a direction (upward direction) away from the attraction surface 300 at both outer peripheral portions on the X-axis (axis of convex bending), and the lower wafer W2 does not receive any force (external force) at both outer peripheral portions on the Y-axis (axis of concave bending). As a result, both outer peripheral portions on the axis of the convex bending of the lower wafer W2 are transformed in a direction allowing it to become flat with respect to the central portion thereof, thus reducing the residual stress. Further, both outer peripheral portions on the axis of the concave bending become closer in a direction in which the concave bending is eliminated (so as to be closer to the attraction surface 300) in conjunction with the transformation on the X-axis, so that the residual stress can be reduced.

In other words, as the air is discharged (external force is applied) to the outer peripheral portions on the axis of the convex bending by the lower chuck 231, the lower wafer W2 is made to have a substantially flat shape in overall. As a result, the lower wafer W2, which has the residual stress directed inwards due to the bending, becomes to have an improved distribution of the residual stress. Then, while the air is being discharged from the zones ch5 and ch6, the control device 90 attracts and holds both outer peripheral portions of the lower wafer W2 on the axis of the concave bending that face the zones ch7 and ch8. Furthermore, the control device 90 generates the attracting pressure in the zones ch5 and ch6 after stopping the discharge of the air. As a consequence, the lower chuck 231 can successfully attract and hold the outer peripheral portions of the lower wafer W2 having the reduced residual stress in the zones ch5 and ch6.

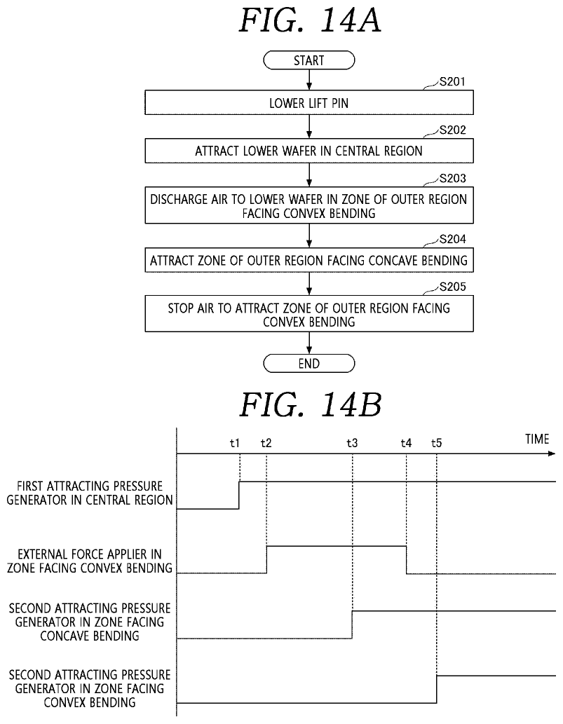

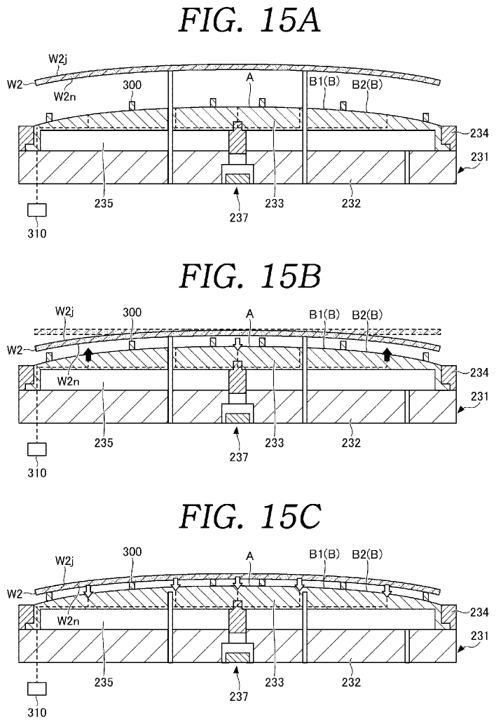

The bonding apparatus 1 according to the present exemplary embodiment is basically configured as described above. Hereinafter, an operation in a substrate placing method of attracting and holding the lower wafer W2 on the lower chuck 231 will be described with reference to FIG. 14A to FIG. 15C. FIG. 14A is a flowchart illustrating an operation sequence when placing the lower wafer W2 on the lower chuck 231. FIG. 14B is a timing chart at the time of placing the lower wafer W2 on the lower chuck 231. FIG. 15A is a diagram illustrating a first operation example in which the lower wafer W2 is placed on the lower chuck 231. FIG. 15B is a diagram illustrating a second operation example in which the lower wafer W2 is placed on the lower chuck 231. FIG. 15C is a diagram illustrating a third operation example in which the lower wafer W2 is placed on the lower chuck 231.

When the lower wafer W2 is carried into the bonding module 41 by the transfer device 61, the control device 90 raises the respective lift pins 265 of the lower chuck 231 to receive the lower wafer W2, and then lowers the lift pins 265 (process S201 in FIG. 14A). Before the lower wafer W2 is carried in, the axis of the convex bending of the lower wafer W2 is adjusted by the second position adjusting device 52 into the direction aligned with the X-axis or Y-axis, as illustrated in FIG. 15A. Further, FIG. 15A to FIG. 15C illustrate an example where the convex bending has occurred along the X-axis of the lower chuck 231.

Then, the control device 90 operates the first attracting pressure generator 321 at the time when the lower wafer W2 is lowered to become sufficiently close to the attraction surface 300, thus allowing the central portion of the lower wafer W2 to be attracted in the zone ch1 as the central region A (process S202 in FIG. 14A). As a result, as shown in FIG. 15B, the central portion of the lower wafer W2 is fixed to the central region A.

The control device 90 operates the external force appliers 330 in the zones ch5 and ch6, which are the areas of the second outer region B2 (outer region B) facing the axis of the convex bending, to discharge the air to the facing surface (non-bonding surface W2n) of the lower wafer W2 in the zones ch5 and ch6 (process S203 in FIG. 14A). As a result, the force is applied to both outer peripheral portions of the lower wafer W2 on the axis of the convex bending in the direction away from the attraction surface 300 (in the direction in which the convex bending is alleviated). Then, the lower wafer W2 is transformed so that it has the flat shape in overall including the concavely bent portion, so that the residual stress caused by the bending is alleviated.

In the state that the air is discharged to both outer peripheral portions on the axis of the convex bending, the control device 90 operates the second attracting pressure generators 322 in the zones ch7 and ch7 of the second outer region B2, which are the areas of the second outer region B2 facing the axis of the concave bending, to attract the lower wafer W2 (process S204 in FIG. 14A). As a result, both outer peripheral portions of the lower wafer W2 on the axis of the concave bending are first attracted and held by the attraction surface 300, so that both outer peripheral portions are suppressed from being concavely bent again.

Finally, the control device 90 operates the second attracting pressure generators 322 in the zones ch5 and ch6, which are areas of the second outer region B2 facing the convex bending, to allow the facing surface (non-bonding surface W2n) of the lower wafer W2 to be attracted in the zones ch5 and ch6 (process S205 in FIG. 14A). As a result, the outer peripheral portions of the lower wafer W2 on the axis of the convex bending are attracted to the attraction surface 300 in the state that the residual stress is alleviated.

That is, through the above-described substrate placing method, the lower chuck 231 can fix the lower wafer W2 in the state that the distribution of the residual stress of the lower wafer W2 is improved. In this state, by performing the bonding process of FIG. 10A to FIG. 10C described above, the bonding apparatus 1 is capable of precisely manufacturing the bonded wafer T with suppressed misalignment between the upper wafer W1 and the lower wafer W2.

In addition, the above-described operations of the gas controller 310 by the control device 90 are presented as a timing chart shown in FIG. 14B. That is, in the substrate placing method, the attracting pressure is first generated at time point t1 in the central region A by the first attracting pressure generator 321. Accordingly, the central portion of the lower wafer W2 is fixed to the lower chuck 231. The attracting pressure for attracting the central portion of the lower wafer W2 is continuously applied while the lower chuck 231 is holding the lower wafer W2.

Then, at time point t2, the control device 90 operates the external force applier 330 of the outer region B facing the axis of the convex bending of the lower wafer W2 to discharge the air to both outer peripheral portions of the lower wafer W2 on the axis of the convex bending. Accordingly, the transformation of the lower wafer W2 is accelerated so that the entire lower wafer W2 becomes substantially flat. Additionally, the discharge timing of the air is not limited to after the time point t1, and may be, for example, simultaneous with the time point t1.

The control device 90 operates the second attracting pressure generator 322 of the outer region B facing the axis of the concave bending of the lower wafer W2 at a time point t3 during the discharge of the air to attract both outer peripheral portion on the axis of the concave bending. This attracting pressure for attracting both outer peripheral portions on the axis of the concave bending is continuously applied while the lower chuck 231 is holding the lower wafer W2. Further, the timing for attracting both outer peripheral portions on the axis of the concave bending is not limited to after the time point t2, either, and may be, for example, simultaneous with the time point t2.

The control device 90 stops the operation of the external force applier 330 at a time point t4 (in the state that both outer peripheral portions of the lower wafer W2 on the axis of the concave bending are fixed). Then, at a time point t5 after the time point t4, the control device 90 operates the second attracting pressure generator 322 in the outer region B facing the axis of the convex bending of the lower wafer W2, thus allowing both outer peripheral portions on the axis of the convex bending to be attracted. Further, the timing for stopping the operation of the external force applier 330 is not limited to after the time point t3, and may be, for example, simultaneous with the time point t3. In addition, for the other zones (ch2 to ch4, ch9, and ch10) of the attraction surface 300 of the lower chuck 231, the attraction may be performed in an appropriate order (or all at once) after the time point t5, for example.

As described above, since the bonding apparatus 1 and the substrate placing method employ the external force applier 330 configured to apply the external force to the lower wafer W2, the distribution of the residual stress in the lower wafer W2 can be improved (uniformed). As a result, the misalignment between the upper wafer W1 and the lower wafer W2 is eliminated as much as possible, and the bonding apparatus 1 can bond the upper wafer W1 and the lower wafer W2 with high precision. In particular, the bonding apparatus 1 can promote the transformation of both outer peripheral portions of the lower wafer W2 on the axis of the convex bending by discharging the air from the zone facing the axis of the convex bending of the lower wafer W2. As a result, the transformation of the lower wafer W2 into the flat shape is promoted even along the axis of the concave bending, so that the residual stress can be effectively improved in the whole wafer.

In addition, the external force applier 330 is configured to discharge the air in the zones ch5 to ch8 where the gap between the lower wafer W2 and the lower chuck 231 becomes the smallest in the outer region B in the state that the lower wafer W2 is placed on the attraction surface 300 and yet to be attracted to the attraction surface 300, as shown in FIG. 12C. Accordingly, the stress on the outer peripheral portion of the lower wafer W2, which is a largely bent portion, can be alleviated. Besides, the external force applier 330 discharges the air to both outer peripheral portions of the lower wafer W2 on the axis of the convex bending from symmetrical positions in the outer region B via the central region A, thus allowing the lower wafer W2 to be uniformly transformed.

In addition, by discharging the air to both outer peripheral portions on the axis of the convex bending in the state that the central region A is attracted, the control device 90 is capable of eliminating the positional misalignment of the lower wafer W2, allowing the lower wafer W2 to be transformed appropriately. In addition, by attracting both outer peripheral portions of the lower wafer W2 on the axis of the convex bending after discharging the air by the external force applier 330, the control device 90 enables the lower wafer W2 with the relieved residual stress to be held appropriately.

Further, the substrate processing apparatus (bonding apparatus 1) according to the present disclosure is not limited to the above-described exemplary embodiments, and various modifications may be made. For example, the external force applied to the lower wafer W2 by the external force applier 330 may be a gas other than the air. An example of the other gas may be an inert gas such as He, Ar, or N₂.

Moreover, in the above-described exemplary embodiment, the lower chuck 231 is configured to discharge the air only from the second outer region B2. However, the lower chuck 231 may be configured to discharge the air from the first outer region B1 (ch2 and ch3) facing the axis of the convex bending of the lower wafer W2. For example, when the convex bending occurs on the X-axis, the lower chuck 231 may discharge the air from the zones ch2, ch5, and ch6. Alternatively, when the convex bending occurs on the Y-axis, the lower chuck 231 may discharge the air from the zones ch3, ch7, and ch8. Accordingly, the external force can be applied more stably on the axis of the convex bending of the lower wafer W2, so that the distribution of the residual stress can be improved. In this case, in the lower chuck 231, the amount of the air discharged from the first outer region B1 and the amount of the air discharged from the second outer region B2 may be set to be different. As an example, by setting the amount of the air in the second outer region B2 to be larger than the amount of the air in the first outer region B1, a larger external force can be applied to the vicinity of the outer edge of the lower wafer W2.

Moreover, the control device 90 may adjust the amount of the discharged air based on, for example, a bending amount of the lower wafer W2 that is bent convexly or concavely. As an example, when the bending amount of the lower wafer W2 is large, an increased amount of air may be discharged to the lower wafer W2 from the lower chuck 231, whereas when the bending amount of the lower wafer W2 is small, a reduced amount of air is discharged to the lower wafer W2 from the lower chuck 231. Thus, the bonding apparatus 1 is capable of further appropriately improving the residual stress of the lower wafer W2.

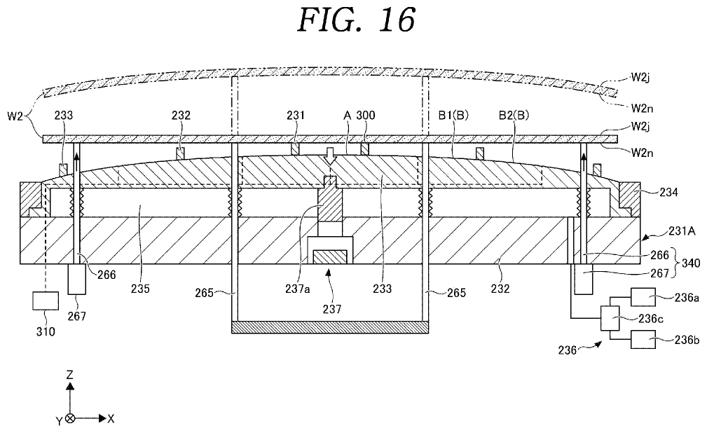

FIG. 16 is a side cross sectional view showing a lower chuck 231A according to a first modification example. As illustrated in FIG. 16, the lower chuck 231A according to the first modification example is different from the above-described lower chuck 231 in that pins 266 configured to be movable up and down relative to the attraction surface 300 is adopted as the external force applier 340 configured to apply the external force to the axis of the convex bending of the lower wafer W2. Specifically, the external force applier 340 is provided with the pins 266 in the zones ch5 to ch8 of the second outer region B2, and also equipped with an elevating mechanism 267 configured to independently move each pin 266 up and down.

The control device 90 raises the pins 266 in regions facing both outer peripheral portions on the axis of the convex bending while holding the central portion of the lower wafer W2 in the central region, thus applying the external force to both outer peripheral portions on the axis of the convex bending in the direction away from the attraction surface 300. Even in this case, the external force applier 340 is capable of improving the distribution of the residual stress in the lower wafer W2. Further, in the configuration having the plurality of pins 266, it becomes possible to apply a stronger external force than in the case of using the air. For example, even in the lower wafer W2 having a large bending amount, the external force applier 340 is capable of improving the residual stress of the lower wafer W2 stably.

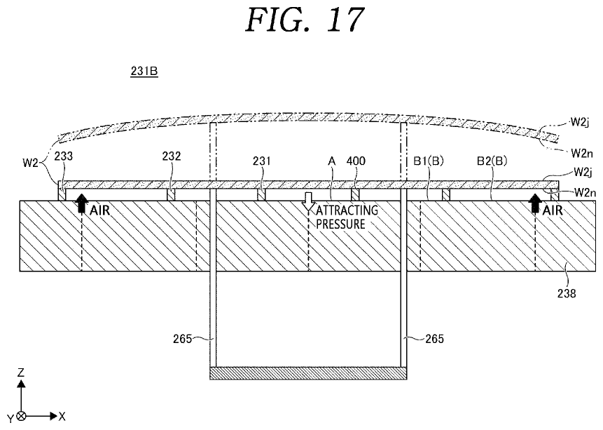

FIG. 17 is a side cross sectional view illustrating a lower chuck 231B according to a second modification example. As depicted in FIG. 17, the lower chuck 231B according to the second modification example is different from the above-described lower chuck 231 in that it has an attraction surface 400 of a flat shape. This flat-shaped attraction surface 400 is also configured to have the central region A and the outer region B, the same as the aforementioned attraction surface 300, and the external force applier 330 configured to be capable of discharging air from an appropriate zone in the outer region B may be applied. In addition, this lower chuck 231B is also capable of relieving the residual stress of the lower wafer W2 by discharging the air to the outer peripheral portions of the lower wafer W2 on the axis of the convex bending from the external force applier 330. Additionally, the external force applier 340 configured to elevate the pins 266 up and down may also be applied to the lower chuck 231B having the attraction surface 400.

It should be noted that the substrate processing apparatus and the substrate placing method according to the exemplary embodiments are illustrative in all respects and are not anyway limiting. The above-described exemplary embodiments can be modified and improved in various ways without departing from the scope and the spirit of claims. Unless contradictory, other configurations may be adopted, and the disclosures in the various exemplary embodiments can be combined appropriately.

According to the exemplary embodiment, it is possible to improve the residual stress distribution of the substrate to appropriately hold the substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus equipped with a holder having, on an attraction surface configured to attract a substrate, a circular central region and an annular outer region disposed outside the central region,
wherein the holder comprises:
a first attracting pressure generator configured to generate an attracting pressure in the central region to attract the substrate to the holder;
a second attracting pressure generator configured to generate an attracting pressure in the outer region to attract the substrate to the holder; and
an external force applier configured to apply an external force to the substrate in the outer region in a direction in which the substrate becomes farther from the holder.

2. The substrate processing apparatus of claim 1,
wherein the external force applier is provided in some of zones of the outer region arranged along a circumferential direction, and applies the external force to a part of a bent outer peripheral portion in the substrate.

3. The substrate processing apparatus of claim 2,
wherein the external force applier applies the external force to a position facing an outer peripheral portion of an axis where convex bending, in which a central portion of the substrate is further away from the attraction surface than the outer peripheral portion thereof, has occurred.

4. The substrate processing apparatus of claim 3,
wherein the external force applier is provided at least in a zone where a gap between the substrate and the holder in the outer region becomes the smallest in a state that the substrate is loaded on the attraction surface and before the substrate is attracted to the attraction surface.

5. The substrate processing apparatus of claim 4,
wherein the external force applier is provided in the zones located at symmetrical positions in the circumferential direction in the outer region with the central region therebetween.

6. The substrate processing apparatus of claim 1,
wherein the external force applier supplies a gas to the holder to discharge the gas, which is the external force, to the substrate from the outer region.

7. The substrate processing apparatus of claim 1,
wherein the external force applier has a pin configured to be moved up and down relative to the attraction surface, and applies the external force by raising the pin to come into contact with the substrate.

8. The substrate processing apparatus of claim 1, further comprising:
a control device configured to control the first attracting pressure generator, the second attracting pressure generator, and the external forcer applier,
wherein the control device attracts the substrate in the central region by the first attracting pressure generator, and applies the external force to the substrate in the outer region by the external force applier.

9. The substrate processing apparatus of claim 8,
wherein the control device attracts the substrate in the outer region by the second attracting pressure generator after applying the external force by the external force applier.

10. The substrate processing apparatus of claim 1,
wherein the substrate includes multiple substrates,
wherein the substrate processing apparatus further comprises:
an upper holder provided vertically above the holder to hold a first substrate, which is a first one of the multiple substrates,
wherein a second substrate, which is a second one of the multiple substrates, is held by the holder, and
the first substrate and the second substrate are bonded by dropping the first substrate from the upper holder.

11. The substrate processing apparatus of claim 1,
wherein the holder has the attraction surface whose central region protrudes higher than the outer region thereof.

12. A substrate placing method of placing a substrate on a holder, which has, on an attraction surface configured to attract the substrate, a circular central region and an annular outer region disposed outside the central region, the substrate placing method comprising:
generating an attracting pressure in the central region to attract the substrate to the holder;
generating an attracting pressure in the outer region to attract the substrate to the holder; and
applying an external force to the substrate in the outer region in a direction causing the substrate to become farther from the holder.
